(19) United States
(12) Patent Application Publication
(10) Pub. No.: US 2015/0198812 A1
(43) Pub. Date: Jul. 16, 2015

(54) Photo-Mask and Accessory Optical Components for Fabrication of Three-Dimensional Structures

(71) Applicant: Georgia Tech Research Corporation, Atlanta, GA (US)

(72) Inventors: Thomas K. Gaylord, Atlanta, GA (US); Matthieu C. Leibovici, Atlanta, GA (US)

(21) Appl. No.: 14/595,912

(22) Filed: Jan. 13, 2015

Related U.S. Application Data
(60) Provisional application No. 61/927,538, filed on Jan. 15, 2014.

(51) Int. Cl. G02B 27/09; G02B 5/32; G03F 7/20; G02B 5/18

(52) U.S. Cl. CPC G02B 27/0944; G02B 5/18; G02B 5/32; G03F 7/20

(57) ABSTRACT

Systems and methods for optical lithography using photo-masks and accessory optical components are disclosed. In one embodiment, a system includes a photo-mask with a body element, one or more diffractive elements, and one or more functional-element-producing features. The diffractive elements can be disposed on or within at least a portion of the body element and can be configured to produce, upon illumination of the photo-mask, multiple beams to form a three-dimensional periodic-optical-intensity pattern in a photosensitive material. The functional-element-producing features can be disposed on or within at least a portion of the body element and can be configured to produce, upon illumination of the photo-mask, a corresponding functional element pattern as an increased optical intensity pattern or decreased optical intensity pattern within the three-dimensional periodic-optical-intensity pattern in the photosensitive material.

### CROSS-REFERENCE TO RELATED APPLICATIONS

This application claims priority to U.S. Provisional Patent Application No. 61/927,538, filed Jan. 15, 2014 and entitled “Photo-Mask and Accessory Optical Components for the Fabrication of Three-Dimensional-Periodic-Based Structures with Projection Lithography,” the entire contents of which is fully incorporated herein by reference.

Some references, which may include patents, patent applications, and various publications, are cited in a reference list and discussed in the disclosure provided herein. The citation and/or discussion of such references is provided merely to clarify the description of the present invention and is not an admission that any such reference is “prior art” to any aspects of the present invention described herein. All references cited and discussed in this specification are incorporated herein by reference in their entireties and to the same extent as if each reference was individually incorporated by reference.

### STATEMENT OF RIGHTS UNDER FEDERALLY-SPONSORED RESEARCH

The present invention was made in part with U.S. Government support under agreement no. ECCS-0925119, awarded by the National Science Foundation. The U.S. Government has certain rights in the invention.

### BACKGROUND

1. Technical Field

The present invention relates to optical lithography, and more particularly to projection lithography.

2. Background of Related Art

Conventional optical lithography systems utilize light to transfer geometric patterns from a photo-mask to a photosensitive material such as a light-sensitive chemical photoresist. Photolithography is commonly used in the semiconductor industry for the fabrication of electrical components such as transistors. While some techniques for producing one-dimensional and two-dimensional functional element patterns are known, the production of three-dimensional patterns by photolithography is less developed. Among other needs, there exists a need for straightforward and cost-effective ways to produce three-dimensional structures by optical lithography. It is with respect to these and other considerations that embodiments of the present invention are directed.

### SUMMARY

Systems and methods according to some embodiments of the present invention address the above-mentioned needs and deficiencies of conventional technologies. Some embodiments of the present invention provide systems and methods for optical lithography using photo-masks and accessory optical components.

According to one aspect, the present invention relates to a system for optical lithography. In some embodiments, the system includes a photo-mask having a body element, one or more diffractive elements, and one or more functional-element producing features. The diffractive elements can be disposed on the body element, within one or more portions of the volume of the body element, or substantially throughout the volume of the body element and can be configured to produce, upon illumination of the photo-mask, multiple beams to form a three-dimensional periodic-optical-intensity pattern in a photosensitive material. The photosensitive material may be a volume photosensitive material. The three-dimensional periodic-optical-intensity pattern can be produced by generating an interference pattern at the photosensitive material.

The functional-element-producing features can be disposed within one or more portions of the body element or substantially throughout the body element, and may be one-dimensional, two-dimensional, or three-dimensional. These features can be configured to produce, upon illumination of the photo-mask, a corresponding functional element pattern as an increased optical intensity pattern or as a decreased optical intensity pattern within the three-dimensional periodic-optical-intensity pattern in the photosensitive material. One or more hologram features can be configured to diffract light to produce the functional element optical intensity pattern in the photosensitive material. The functional-element-producing features can include a combination of hologram features and an absorption volume configured to produce the functional element optical intensity pattern in the photosensitive material. An absorption volume can be configured to attenuate light to produce the functional element optical intensity pattern in the photosensitive material. The functional element optical intensity pattern can be a three-dimensional non-periodic-optical intensity pattern.

In some embodiments, the system can also include additional optical accessory components. One or more beam conditioners can be configured to introduce polarization adjustment, amplitude adjustment, and/or phase shifting in the multiple beams produced by the one or more diffractive elements. For example, the system can include polarizers, attenuators, and/or phase shifting components. The beam conditioners can include a transmissive or reflective spatial light modulator positioned in the Fourier plane.

In another aspect, the present invention relates to a photo-mask. In some embodiments, the photo-mask includes a body element, a plurality of diffractive elements, and one or more three-dimensional functional-element-producing features. The diffractive elements can be disposed on the body element, within one or more portions of the volume of the body element, or substantially throughout the volume of the body element. The diffractive elements can be configured to produce, upon illumination of the photo-mask, multiple beams to form a three-dimensional periodic-optical-intensity pattern in a photosensitive material, which can be a volume photosensitive material. In some embodiments, the multiple beams can be produced such as to form an umbrella configuration of beams.

In some embodiments, the diffractive elements can be disposed within a first portion of the body element while the functional-element-producing features are disposed within a separate, second portion of the body element. For example, the diffractive elements can be disposed within an upper portion of the body element and the functional-element-producing features disposed within a lower portion of the body element. In some embodiments, the plurality of diffractive elements can include a plurality of layers of diffractive elements. The diffractive elements can include diffractive gratings.

The three-dimensional, functional-element-producing features can include a plurality of layers of functional-element-producing features that are disposed within a lower portion of the body element while diffractive elements are disposed in an upper portion of the body element. In some embodiments, the three-dimensional functional-element-producing features can include a channel and/or waveguide.

In another aspect, the present invention relates to a method for fabricating a three-dimensional structure by optical lithography. In some embodiments, the method includes producing, by one or more diffractive elements of a photo-mask, multiple beams to form a three-dimensional optical intensity pattern in a photosensitive material. In some embodiments, the diffractive elements occupy only a portion of the volume of the body element of the photo-mask. Alternatively, the diffractive elements may be disposed throughout the volume of the body element.

The method can also include producing, by one or more functional-element-producing features of the photo-mask, a corresponding functional element pattern as an increased optical intensity pattern or as a decreased optical intensity pattern within the three-dimensional periodic-optical-intensity pattern in the photosensitive material. The functional element intensity pattern can be a three-dimensional, non-periodic optical intensity pattern. Producing the multiple beams to form the three-dimensional optical intensity pattern in the photosensitive material can include producing, by the diffractive elements, the multiple beams to generate an interference pattern in the photosensitive material.

Producing the functional element optical intensity pattern can include diffracting light by a hologram feature of the functional-element-producing feature and/or attenuating light by an absorption volume of the functional-element-producing feature. The method can also include introducing, by one or more beam conditioners, polarization adjustment, amplitude adjustment, and/or phase shifting in the multiple beams produced by the diffractive elements. The beam conditioners can include a transmissive or reflective spatial light modulator positioned in the Fourier plane.

The foregoing and other objects, features, aspects, and advantages of the present invention will become more apparent from the following detailed description of the present invention when taken in conjunction with the accompanying drawings.

### BRIEF DESCRIPTION OF THE DRAWINGS

Reference will now be made to the accompanying drawings, which are not necessarily drawn to scale, and wherein:

FIG. 1 shows an exploded view of a three-dimensional periodic structure with a three-dimensional functional element incorporated within the periodic structure, produced through exposure of a photosensitive material using a photo-mask according to one or more embodiments of the present invention;

FIG. 2 illustrates a projection lithography system including a photo-mask according to one embodiment of the present invention;

FIG. 3 illustrates a photo-mask according to one embodiment of the present invention, which includes volume diffractive gratings and functional elements imbedded within the same volume;

FIG. 4 illustrates a photo-mask according to one embodiment of the present invention, which has volume diffractive gratings in an upper portion and functional elements in a lower portion;

FIG. 5 illustrates a combined volume diffractive photo-mask and functional-element photo-mask according to one embodiment of the present invention;

FIG. 6 illustrates a photo-mask according to one embodiment of the present invention, which has a combination of volume diffractive photo-masks and a functional-element photo-mask;

FIG. 7 illustrates ray trace mapping between a single object point in a photo-mask according one embodiment of the present invention and a corresponding single image point in a photosensitive material;

FIG. 8 illustrates ray trace mapping between multiple object points in a photo-mask according to one embodiment of the present invention and the corresponding multiple image points in the photosensitive material;

FIG. 9 illustrates a photo-mask according to one embodiment of the present invention, which includes attenuation elements and phase elements distributed throughout the volume of the photo-mask, and wherein each element in the photo-mask corresponds to an image element in a photosensitive material;

FIG. 10 illustrates a holographic recording configuration for producing holograms according to one or more embodiments of the present invention, with a reference wave and subject wave being present simultaneously;

FIG. 11 illustrates wavefronts of a reference wave and subject wave, wherein an interference fringe pattern between the wavefronts records a hologram according to one or more embodiments of the present invention and which, when illuminated with the reference wave, reconstructs the image point in a photosensitive material;

FIG. 12 illustrates a photo-mask with functional element holograms according to one embodiment of the present invention, wherein each functional-element hologram reconstructs one of the image points in a photosensitive material;

FIG. 13 illustrates an umbrella configuration of wavevectors produced by a photo-mask according to one or more embodiments of the present invention and then incident upon a volume photosensitive material;

FIG. 14 illustrates wavevectors incident upon photosensitive material and producing a three-dimensional periodic optical intensity pattern in a volume photosensitive material, according to one embodiment of the present invention;

FIG. 15 illustrates a projection lithography optical system including a photo-mask and with additional accessory optical components inserted in the Fourier plane, according to an embodiment of the present invention;

FIG. 16 illustrates accessory optical components according to one embodiment of the present invention, for introducing phase shifting, polarization adjustment, and attenuating functions into the zero-order beam and diffracted beams produced by a photo-mask according to one or more embodiments of the present invention; and

FIG. 17 is a flow diagram illustrating operations of a method for fabricating a three-dimensional structure by optical lithography, in accordance with one embodiment of the present invention.

### DETAILED DESCRIPTION

The following detailed description is directed to systems and methods using photo-masks and accessory optical components in optical lithography. Although exemplary embodiments of the present invention are explained in detail, it is to be understood that other embodiments are contemplated. Accordingly, it is not intended that the present invention is limited in its scope to the details of construction and arrangement of components set forth in the following description or illustrated in the drawings. The present invention is capable of other embodiments and of being practiced or carried out in various ways. Also, in describing the preferred embodiments, specific terminology will be resorted to for the sake of clarity.

It must also be noted that, as used in the specification and the appended claims, the singular forms “a,” “an” and “the” include plural referents unless the context clearly dictates otherwise.

Also, in describing the preferred embodiments, terminology will be resorted to for the sake of clarity. It is intended that each term contemplates its broadest meaning as understood by those skilled in the art and includes all technical equivalents that operate in a similar manner to accomplish a similar purpose.

Ranges may be expressed herein as from “about” or “approximately” one particular value and/or to “about” or “approximately” another particular value. When such a range is expressed, another embodiment includes from the one particular value and/or to the other particular value.

By “comprising” or “containing” or “including” is meant that at least the named compound, element, particle, or method step is present in the composition or article or method, but does not exclude the presence of other compounds, materials, particles, method steps, even if the other such compounds, material, particles, method steps have the same function as what is named.

It is also to be understood that the mention of one or more method steps does not preclude the presence of additional method steps or intervening method steps between those steps expressly identified. Method steps may be performed in a different order than those described herein. Similarly, it is also to be understood that the mention of one or more components in a device or system does not preclude the presence of additional components or intervening components between those components expressly identified.

In the detailed description, references are made to the accompanying drawings that form a part hereof and that show, by way of illustration, specific embodiments or examples. In referring to the drawings, like numerals represent like elements throughout the several figures.

According to some aspects of the present invention, a photo-mask enables the fabrication of three-dimensional periodic-based structures with or without embedded non-periodic functional elements. In some embodiments, a photo-mask contains volume diffractive grating elements and can be configured for use in a projection lithography system, which may be a conventional projection lithography system. Under illumination, the diffractive photo-mask can produce multiple beams which, through lithographic objective lenses, are caused to be incident upon a photosensitive material such as a photoresist film.

Whereas conventional two-dimensional area exposures may produce a two-dimensional pattern, a photo-mask in accordance with some embodiments of the present invention can enable a three-dimensional volume exposure producing a three-dimensional periodic pattern. In addition, the three-dimensional periodic structure may have one-dimensional, two-dimensional, and/or three-dimensional functional elements embedded within it due to corresponding patterns incorporated in the photo-mask. Further, contrast and position of the pattern can be adjusted by the addition of accessory optical components in the Fourier plane that may introduce phase shifting, polarization adjustment, and/or attenuation adjustment in the individual zero-order and diffracted beams produced by the photo-mask, for high-contrast interference.

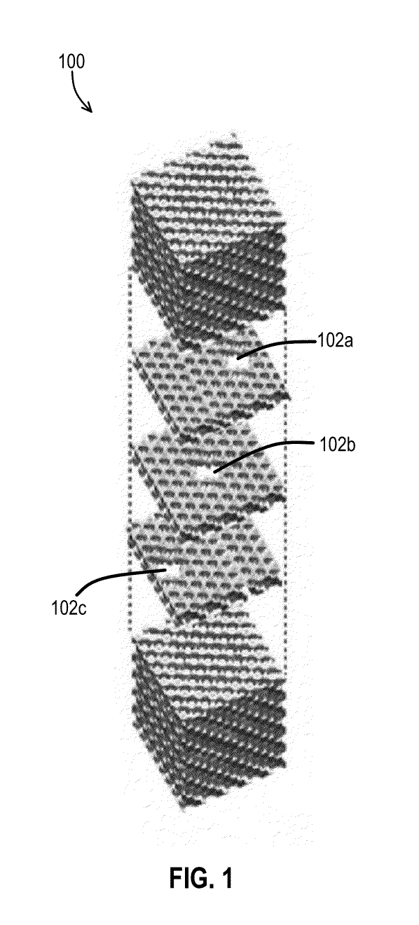

A photo-mask according to some embodiments of the present invention can provide for the fabrication of three-dimensional periodic-based structures with or without embedded non-periodic functional elements. FIG. 1 shows an exploded view of a three-dimensional periodic structure 100 with a three-dimensional functional element 102a, 102b, 102c (collectively 102) incorporated within the periodic structure 100, produced through exposure of a photosensitive material such as a photoresist film by a photo-mask in accordance with one or more embodiments of the present invention.

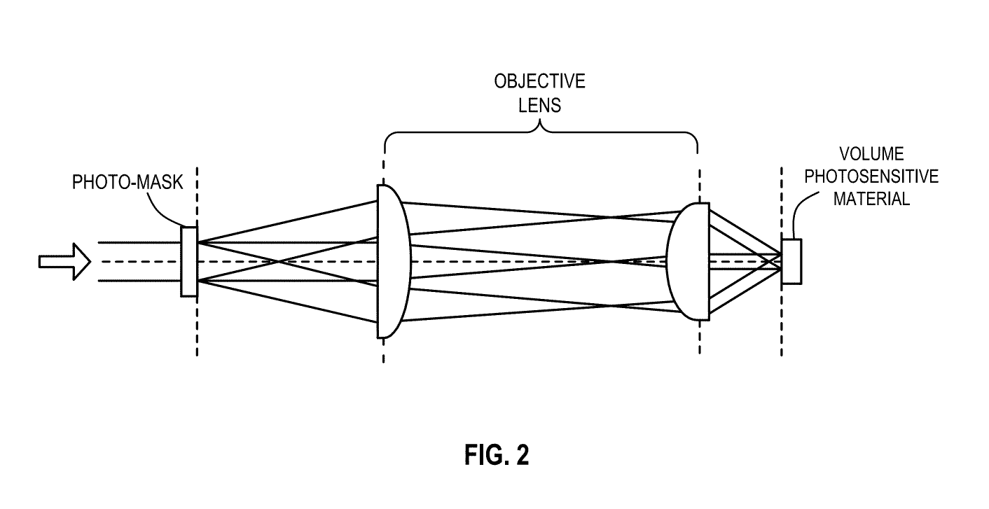

In some embodiments of the present invention, a photo-mask can contain volume diffractive elements and can be configured for use in a projection lithography system. Now referring to the projection lithography system shown in FIG. 2, when substituted for a conventional two-dimensional pattern photo-mask, the volume diffractive elements of the photo-mask may be displaced from the optical object plane. In their displaced positions, the volume diffractive elements are effectively out of focus at the volume photosensitive material. Alternatively, the volume diffractive elements can be located throughout the entire volume of the photo-mask. Functional elements can be located at or near the optical object plane, and these functional elements, which may be two-dimensional or three-dimensional, can be imaged within the resulting three-dimensional intensity pattern at the volume photosensitive material.

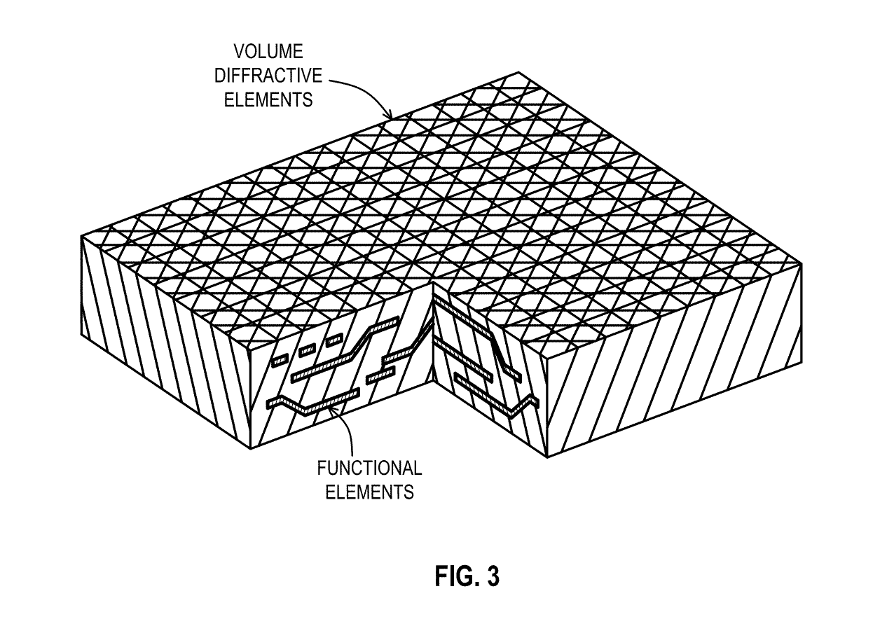

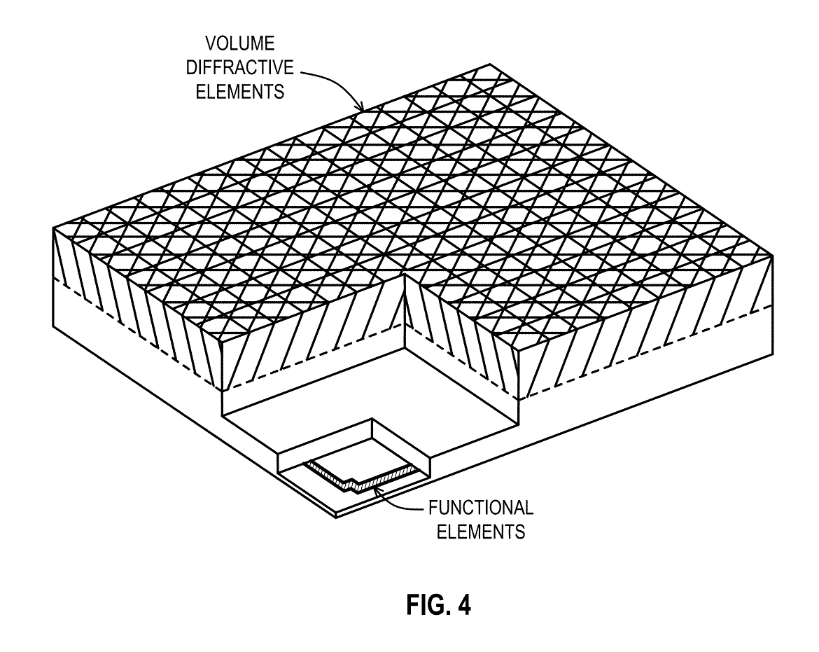

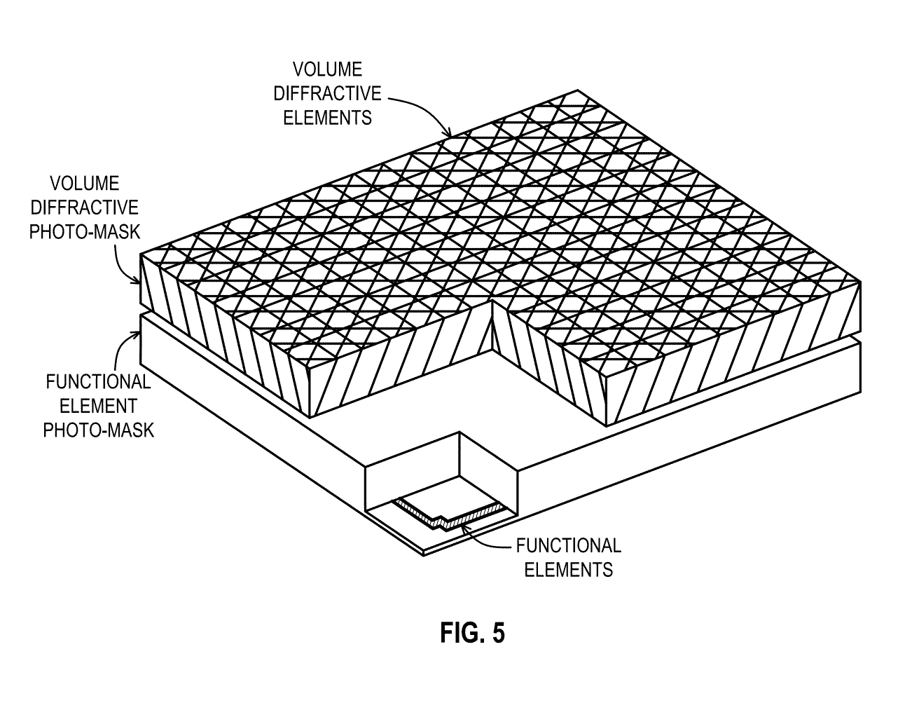

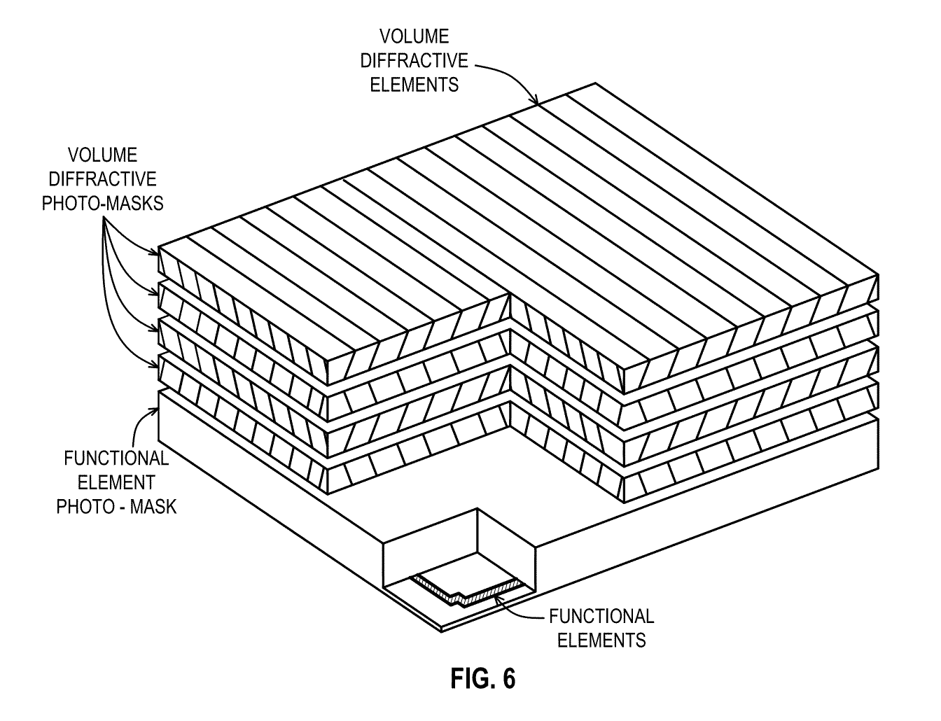

As shown in FIG. 3, in some embodiments of the present invention, volume diffractive elements and functional elements may be superposed within the same volume of a photo-mask. As shown in FIG. 4, volume diffractive elements and functional elements can reside in separate regions within the same single photo-mask. Alternatively, in some embodiments of the invention, for example as shown in FIG. 5, a photo-mask may be comprised of separate pieces or layers, for example one layer with the volume diffractive elements and one layer with the functional elements. Further, the functional elements may be distributed on two or more separate masks that are combined to perform the exposure. Still further, as shown in FIG. 6, in some embodiments volume diffractive elements may be in separate pieces. In this configuration, the diffracted beams are not further diffracted by the subsequent gratings due to the Bragg selectivity of the volume gratings. Thus, the diffracted waves do not interact with the other gratings. The group of gratings may be designed to produce equal diffracted intensities or a specified ratio of intensities. For example, to produce equal diffracted intensities, the diffraction efficiencies of each subsequent grating are correspondingly larger, since the zero-order beam loses some power due to preceding gratings.

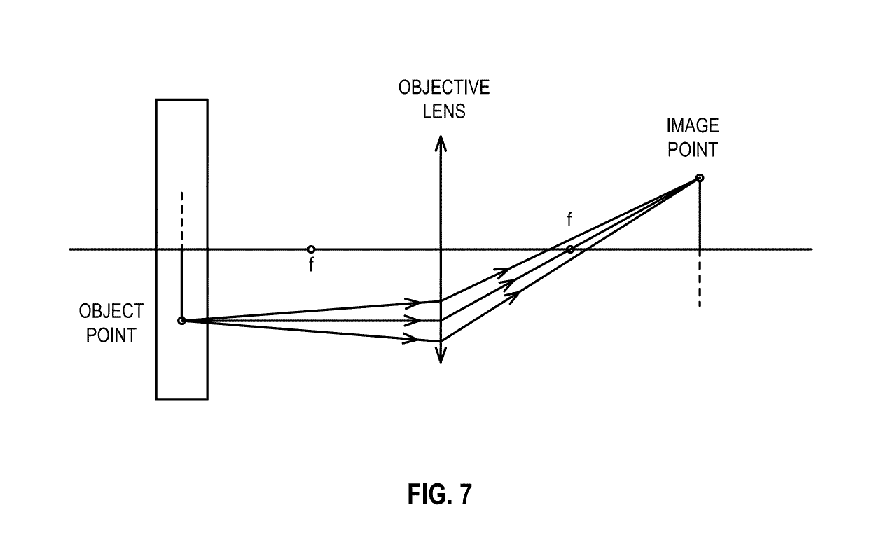

FIG. 5 illustrates a combined volume diffractive photo-mask and functional-element photo-mask according to one embodiment of the present invention. FIG. 6 illustrates a photo-mask according to one embodiment of the present invention, which has a combination of volume diffractive photo-masks and a functional-element photo-mask. FIG. 7 illustrates ray trace mapping between a single object point in a photo-mask according one embodiment of the present invention and a corresponding single image point in a photosensitive material.

Diffractive grating elements in accordance with some embodiments of the present invention may be designed by Rigorous Coupled Wave Analysis (RCWA) [Gaylord_{—}1985] or Finite-Difference Time Domain (FDTD) analysis, among other methods. The specified ratio of intensities of the zero-order beam to the non-zero-order beams can be controlled by adjusting the relative strengths of the gratings. Diffractive gratings in a photo-mask in accordance with some embodiments of the present invention can be fabricated by a series of two-beam exposures of the photosensitive volume. The mask material may be a photorefractive material such as lithium niobate.

For embodiments in which the volume diffractive elements and the functional elements are in separate masks, for example as shown in FIG. 5 and FIG. 6, a diffractive mask may be a photorefractive crystal such as lithium niobate and a functional-element mask may be conventional photo-mask glass such as fused quartz. A diffractive photo-mask (with or without embedded functional elements) in accordance with some embodiments of the present invention may be produced by direct writing of the designed diffractive grating elements and functional elements, for example through the use of laser, electron, ion, and/or x-ray beam writing technologies.

Functional elements of photo-masks according to some embodiments of the present invention will now be described in further detail. Functional elements can comprise one-dimensional, two dimensional, and/or three-dimensional patterns and may be implemented as amplitude/phase elements or as holographic elements. One-dimensional and two-dimensional functional elements may be implemented using conventional photo-mask making techniques, wherein each point in planar object space (photo-mask) is imaged to a corresponding image point in planar image space (photoresist) as described by the lens equation

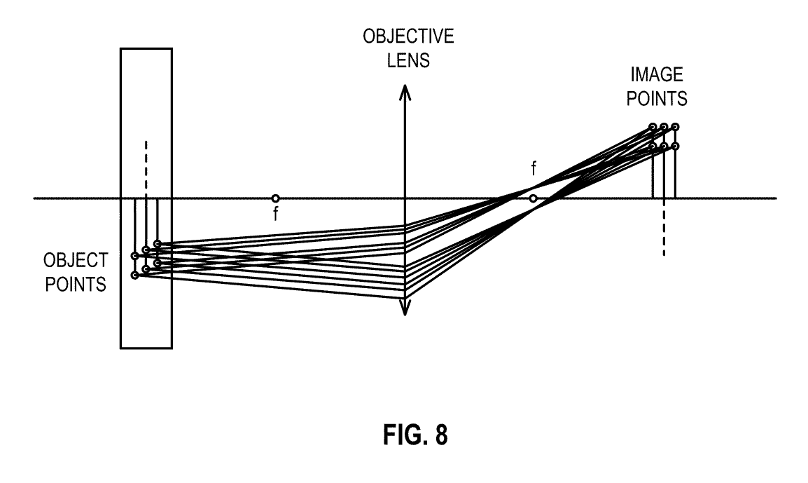

1/s+1/s′=1/f (1)

where s is the object distance, s′ is the image distance, and f is the focal length of the objective lens, as illustrated through ray tracing in FIG. 8. Three-dimensional elements in the image space (photoresist) require three-dimensional functional elements in the object space, as illustrated through ray tracing in FIG. 8. In this example, six points forming a three-dimensional image in image space are produced by six points forming a three-dimensional object in object space. For each object point, the linear lateral magnification m in image space is given by

m=−s′/s (2)

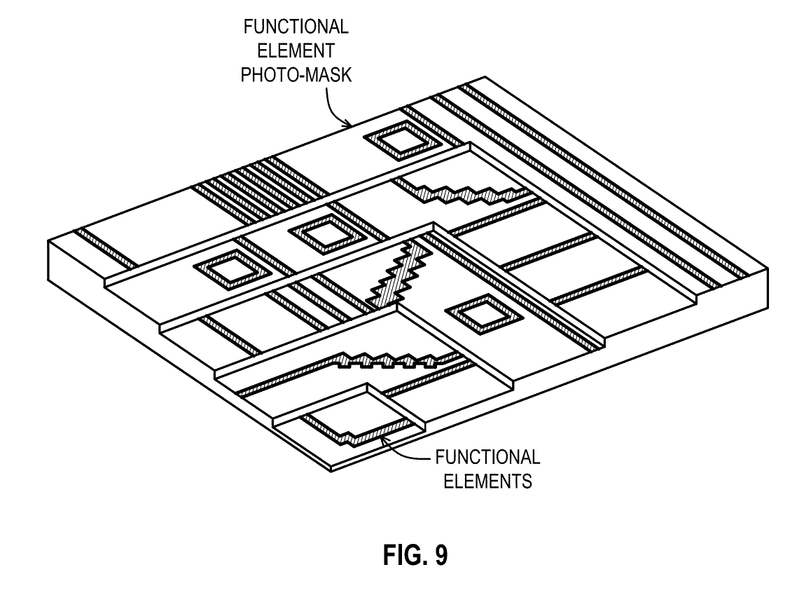

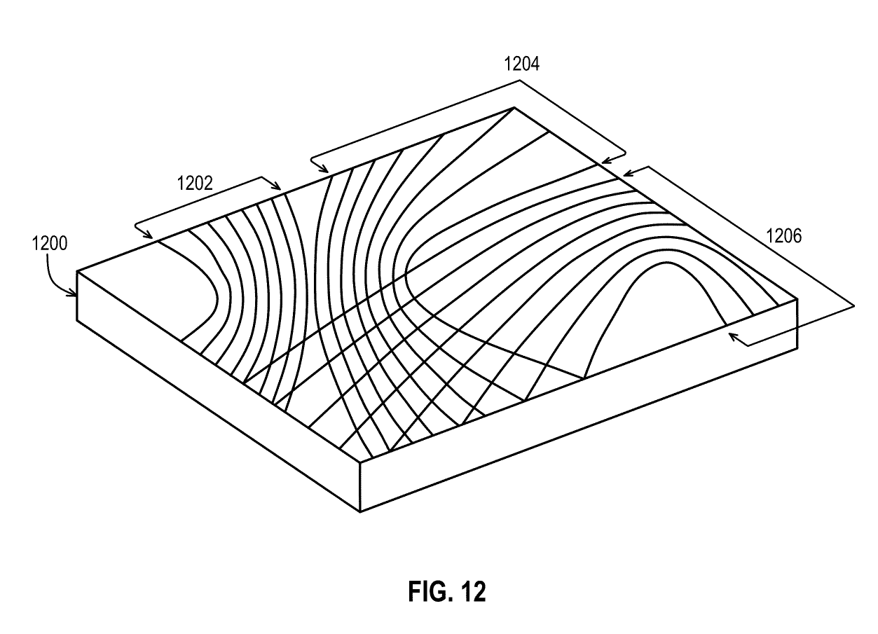

As the position of an image point changes along the optical axis (a change in s′), the position of the object point along the optical axis must correspondingly change (a change in s), which is accompanied by a corresponding change in the magnification. For a three-dimensional image, the functional-element photo-mask can have elements distributed throughout its volume, with object distances and magnifications chosen so as to produce the desired image exposure. FIG. 9 shows a functional-element photo-mask according to an embodiment of the invention, comprised of attenuation and phase elements distributed throughout the volume of the functional-element photo-mask. Each element in the functional-element photo-mask (object points) corresponds to an image element (image point) in the photoresist. The photo-mask of FIG. 9 selectively attenuates and/or changes the phase of the light, and thus corresponding locations in the photoresist do not receive illumination. Using negative photoresist, these unilluminated locations cause the photoresist not to be developed (no cross-linking of polymers), whereas in illuminated areas, the photoresist is developed (cross-linking occurs). This process thus records the pattern of the functional-element photo-mask. Light may be added by utilizing functional element holograms (see, e.g., FIG. 12 discussed in detail below) and positive photoresist to produce additional exposure.

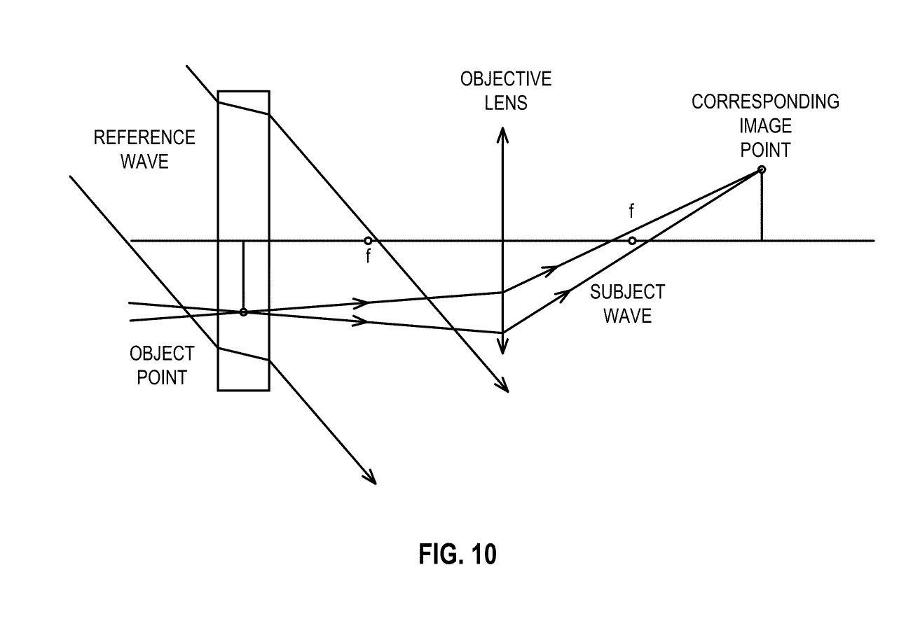

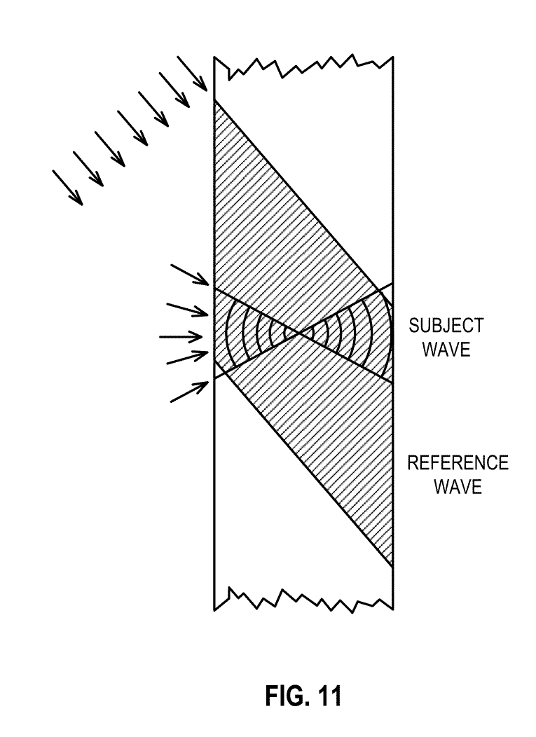

In some embodiments of the present invention, a functional-element photo-mask can be based on holographic recordings wherein each object point is represented as a light source. The interference between this point light source and a reference wave can be recorded (a hologram). FIG. 10 shows a holographic recording configuration with the reference wave (plane wave) and the subject wave (spherical wave due to a single point object) being present simultaneously. The wavefronts of the reference wave and the subject wave of FIG. 10 are shown in FIG. 11. The recorded interference fringe pattern between the wavefronts records the hologram which, when illuminated with the reference wave (produced by diffraction of one of the volume gratings in the photo-mask), reconstructs the image point in the photoresist.

The total functional-element holographic photo-mask according to some embodiment can consist of the superposition of all of the holograms for all of the point sources. This hologram can be constructed by optical recording as described above, or the holographic pattern can be calculated by the methods used to construct computer-generated holograms. The configuration of the beams may be the same as that which occurs in shift-multiplexing for high-capacity holographic data storage [Barbastathis_{—}1996], [Yoshida_{—}2013], [Gombkoto_{—}2006]. The calculated functional-element photo-mask may be implemented by laser, electron, ion, or x-ray beam, for example.

FIG. 12 shows a functional-element photo-mask 1200 comprised of multiple functional-element holograms 1202, 1204, 1206 that may be superposed, provided across the same layer of the functional-element photo-mask, or located at different layers at various depths within the volume of the functional-element photo-mask. Each functional-element hologram reconstructs one of the image points in the photoresist. FIG. 12 can be considered to represent FIG. 11 where, in addition to changing point-by-point an amplitude or phase in the functional-element photo-mask, a point source, effectively, can be produced point-by-point, represented by FIG. 11. When taking into account the interference between the waves shown by FIG. 11, a more general pattern is produced, and FIG. 12 shows one such exemplary pattern. Accordingly, FIG. 12 represents interference fringes associated with one or more of the point sources of light produced within the photo-mask, which then exposes the photosensitive material within the three-dimensional periodic structure that is produced. There can be the point source exposures in specific regions, which may form through positive type photoresist type materials formed into three-dimensional structures such as channels or resonators.

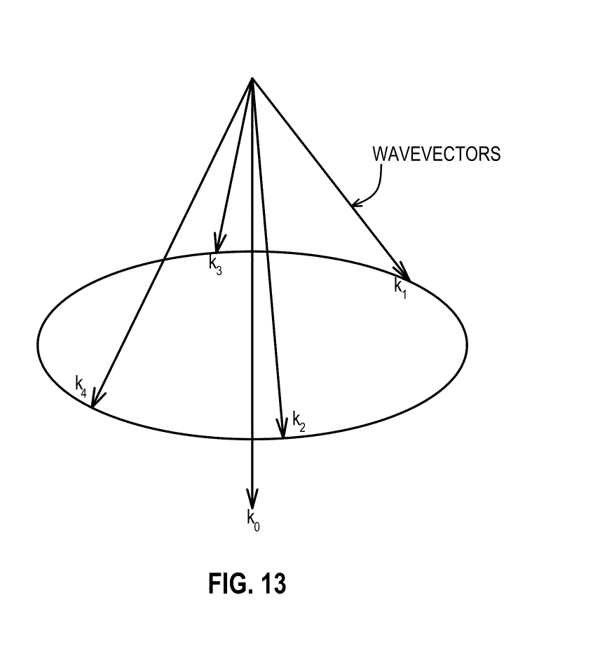

FIG. 13 shows an umbrella configuration of reference beam wavevectors k₀, k₁, k₂, k₃, k₄ that may be produced by a volume diffractive photo-mask according to an embodiment of the present invention and then incident upon a volume photosensitive material to produce three-dimensional functional element patterns in the volume photosensitive material. Although there are five beams shown in the example configuration of FIG. 13, there may be other numbers of beams in alternative configurations, provided there are at least four beams to produce the three-dimensional periodic pattern. Wavevectors k₀, k₁, k₂, k₃, k₄ are perpendicular to the planes of the constant phase in the plane waves that are interfering to produce the three-dimensional periodic pattern. Although not specifically shown in FIG. 13, functional elements can be produced by a photo-mask according to embodiments of the present invention, where the functional elements correspond to disruptions in the three-dimensional periodic pattern. The functional elements may be channels, resonators, rings, paths for circuitry or microfluidics, or other types of elements within the three-dimensional periodic pattern.

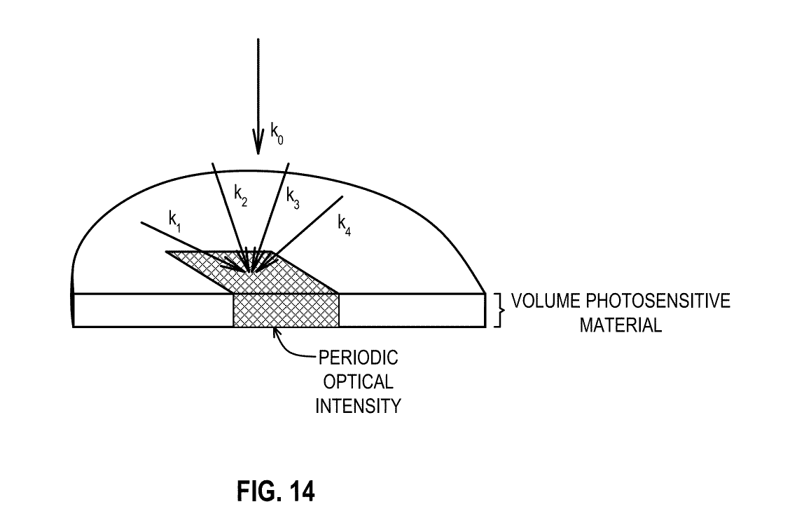

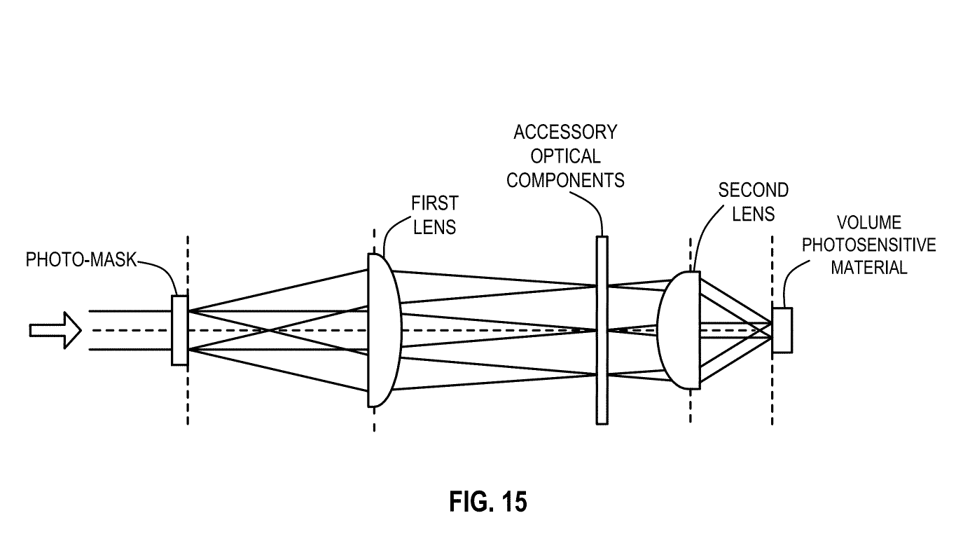

FIG. 14 shows wavevectors incident upon a volume photosensitive material and producing a three-dimensional periodic optical intensity pattern in the volume photosensitive material, by using a photo-mask according to an embodiment of the present invention. Comparing FIG. 13 with FIG. 14 and FIG. 15, FIG. 13 shows wavevectors incident upon a sample plane, for example at a volume photosensitive material at a sample plane. In the illustration of FIG. 13, wavevectors k₀-k₄ are illustrated as emerging from a common point. This configuration may correspond to wavevectors that result from an incident beam upon the photo-mask and separating from photo-mask into multiple wavevectors propagating towards a first lens. In the illustration of FIG. 14, wavevectors k₀-k₄ are shown as converging towards a common point, which may correspond to wavevectors recombining as they pass from a second lens to the sample plane at the volume photosensitive material shown in FIG. 15.

In operation, a photo-mask in accordance with one or more embodiments of the present invention may be illuminated by a single expanded optical beam. In some embodiments of the present invention, the beam can be linearly polarized, and effects of the constrained polarization are described in [Burrow_{—}2012c]. In some embodiments of the present invention, additional accessory optical components provide for the adjustment, to any arbitrary state, of the amplitude, polarization, and/or phase. In this manner, primitive-lattice-vector-direction equal contrasts can be achieved as described in [Stay_{—}2009].

Such accessory optical components can be inserted at or near the Fourier plane in a projection lithography system as shown in FIG. 15. The accessory optical components can include elements that introduce phase shifting, polarization adjusting, and/or attenuating functions into the zero-order beam and into the diffracted beams that are produced by the photo-mask. These elements may be separate or may be integrated together. A transmissive or reflective spatial light modulator may be used to provide all or a portion of these functions.

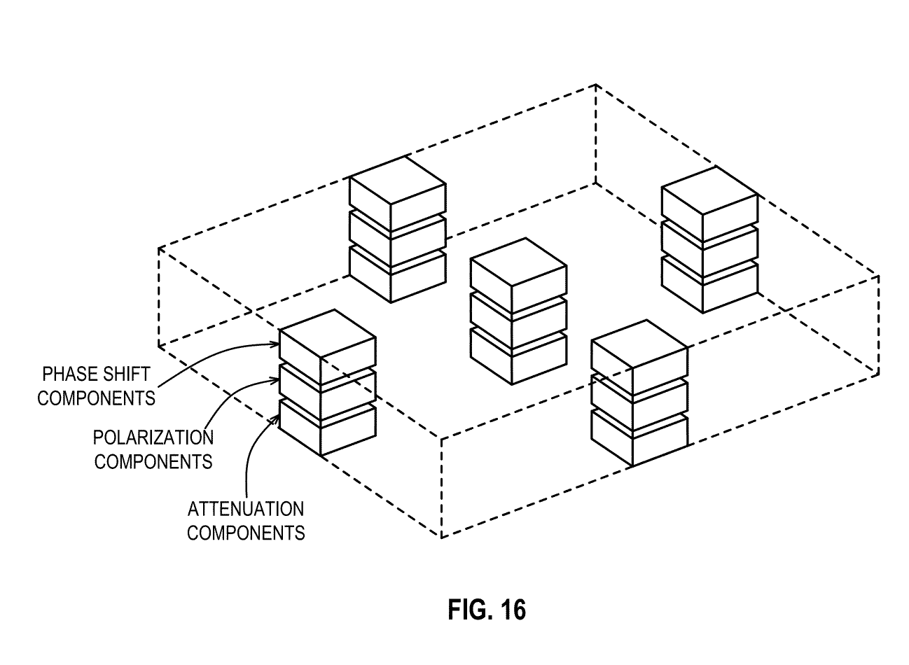

FIG. 16 is a schematic representation of accessory optical components that introduce phase shifting, polarization adjusting, and attenuation functions into the zero-order beam (center three elements) and diffracted beams (four surrounding groups of three elements) produced by a photo-mask according to some embodiments of the present invention. For example, attenuation components may comprise absorption layers, and phase shifting can be performed by introducing extra path length or by utilizing a block with a higher refractive index. Because the formation of a three-dimensional interference pattern can highly depend upon polarization, it can be desirable to use one or more polarization components such as waveplates (e.g., half-wave plates to rotate polarization) to adjust polarization for forming optimal high-contrast three-dimensional patterns.

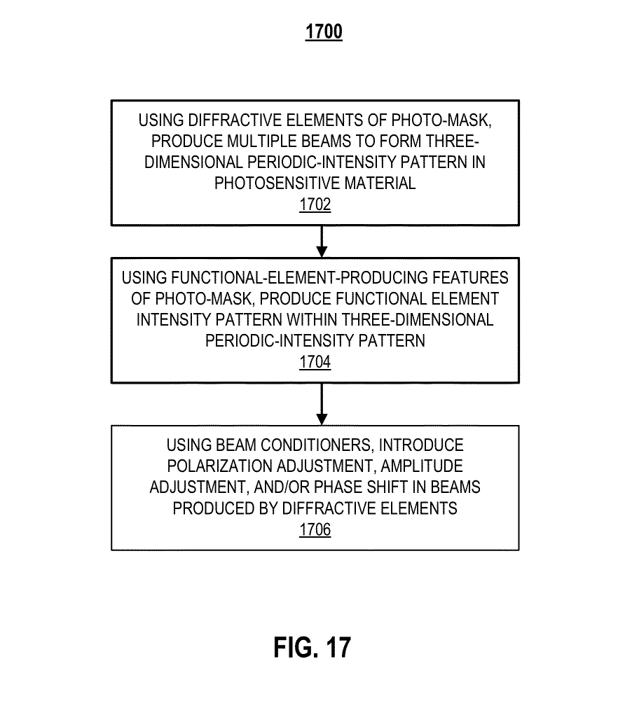

FIG. 17 is a flow diagram illustrating operations of a method 1700 for fabricating a three-dimensional structure by optical lithography, in accordance with one embodiment of the present invention. At block 1702, using one or more diffractive elements of a photo-mask, upon illumination of the photo-mask, multiple beams are produced to form a three-dimensional periodic—intensity pattern in a photosensitive material. The diffractive elements can be disposed on, within one or more portions of, or substantially throughout a body element of the photo-mask. At block 1704, using one or more functional-element-producing features of the photo-mask and upon illumination of the photo-mask, a corresponding functional element pattern, as an increased intensity pattern or as a decreased intensity pattern, is produced within the three-dimensional periodic-intensity pattern in the photosensitive material. At block 1706, one or more beam conditioners are used to introduce polarization adjustment, amplitude adjustment, and/or phase shifting in the multiple beams produced by the diffractive elements. The beam conditioners can be disposed on, within one or more portions of, or substantially throughout the body element of the photo-mask.

Photo-masks and accessory optical components according to embodiments of the present invention have practical applications across numerous fields. For example, and not limited to—three-dimensional functional elements formed in accordance with some embodiments of the present invention can be formed as channels or waveguides to control the propagation of light through a structure. The three-dimensional functional elements may also be implemented in biological and chemical settings, for example to form channels or microwells for use in microfluidics implementations and/or forming bioscaffolds for tissue growth. Embodiments of the present invention may also be employed in the field of photonic crystal devices, for example to produce efficient fiber-optic couplers, or for texturing of solar cells. Further applications include microelectronics, nanoelectronics, micro-electro-mechanical systems (MEMS), and communication or thermal transfer in computing devices.

Numerous characteristics and advantages have been set forth in the foregoing description, together with details of structure and function. While various embodiments of the processing systems and methods have been disclosed in exemplary forms, many modifications, additions, and deletions can be made without departing from the spirit and scope of the present invention and its equivalents as set forth in the following claims. Therefore, other modifications or embodiments as may be suggested by the teachings herein are particularly reserved as they fall within the breadth and scope of the claims here appended.

### REFERENCES

[Gaylord_{—}1985] T. K. Gaylord and M. G. Moharam, “Analysis and applications of optical diffraction by gratings,” Proc. IEEE, vol. 73, pp. 894-937, May 1985.
[Barbastathis_{—}1996] G. Barbastathis, M. Levene, and D. Psaltis, “Shift multiplexing with spherical reference waves,” Applied Optics, vol. 35, pp. 2403-2417, May 10, 1996.
[Yoshida_{—}2013] S. Yoshida, H. Kurata, S. Ozawa, K. Okubo, S. Horiuchi, Z. Ushiyama, M. Yamamoto, S. Koga, and A. Tanaka, “High-density holographic data storage using three-dimensional shift multiplexing with spherical reference wave,” Jpn. J. Appl. Phys., vol. 52, pp. 09LD07-1-5, 2013.
[Gombkoto_{—}2006] B. Gombkoto, P. Koppa, P. Maak, and E. Lorincz, “Application of the fast-Fourier-transform-based volume integral equation method to model volume diffraction in shift-multiplexed holographic data storage,” J. Opt. Soc. Am. A, vol. 23, pp. 2954-2960, November 2006.
[Burrow_{—}2012c] G. M. Burrow and T. K. Gaylord, “Parametric constraints in multi-beam interference,” J. Micro/Nanolithography, MEMS, and MOEMS., vol. 11, pp. 043004-1-043004-8, October-December 2012.
[Stay_{—}2009] J. L. Stay and T. K. Gaylord, “Conditions for primitive-lattice-vector-direction equal contrasts in four-beam-interference lithography,” Appl. Opt., vol. 48, pp. 4801-4813, Aug. 20, 2009.

What is claimed is:

1. A system for optical lithography, comprising:
a photo-mask comprising:
a body element;
at least one diffractive element disposed on or within at least a portion of the body element and configured to produce, upon illumination of the photo-mask, multiple beams to form a three-dimensional periodic-optical-intensity pattern in a photosensitive material; and
at least one functional-element-producing feature disposed within at least a portion of the body element and configured to produce, upon illumination of the photo-mask, a corresponding functional element pattern as an increased optical intensity pattern or decreased optical intensity pattern within the three-dimensional periodic-optical-intensity pattern in the photosensitive material.

2. The system of claim 1, wherein the at least one functional-element-producing feature comprises a hologram feature configured to diffract light to produce the functional element optical intensity pattern in the photosensitive material.

3. The system of claim 1, wherein the at least one functional-element-producing feature comprises an absorption volume configured to attenuate light to produce the functional element optical intensity pattern in the photosensitive material.

4. The system of claim 1, wherein the at least one functional-element-producing feature comprises a combination of a hologram feature and absorption volume configured to produce the functional element optical intensity pattern in the photosensitive material.

5. The system of claim 1, wherein the functional-element-producing feature is a three-dimensional feature.

6. The system of claim 1, wherein the at least one diffractive element occupies only a portion of the volume of the body element.

7. The system of claim 1, wherein the at least one diffractive element is configured to produce, upon illumination of the photo-mask, the multiple beams to generate an interference pattern in the photosensitive material.

8. The system of claim 1, wherein the functional-element-producing feature is configured to produce, upon illumination of the photo-mask, a three-dimensional non-periodic-optical-intensity pattern in the photosensitive material.

9. The system of claim 1, wherein the photosensitive material is a volume photosensitive material.

10. The system of claim 1, further comprising at least one beam conditioner configured to introduce at least one of polarization adjustment, amplitude adjustment, and phase shifting in the multiple beams produced by the at least one diffractive element.

11. The system of claim 1, further comprising at least one polarizer, attenuator, or phase shifter.

12. The system of claim 10, wherein the at least one beam conditioner comprises a transmissive or reflective spatial light modulator.

13. The system of claim 10, wherein the at least one beam conditioner is positioned in the Fourier plane.

14. A photo-mask, comprising:
a body element;
a plurality of diffractive elements disposed within at least a portion of the body element and configured to produce, upon illumination of the photo-mask, multiple beams to form a three-dimensional periodic-optical-intensity pattern in a photosensitive material; and
at least one three-dimensional functional-element-producing feature disposed within at least a portion of the body element and configured to produce, upon illumination of the photo-mask, a corresponding functional element pattern as an increased optical intensity pattern or decreased optical intensity pattern within the three-dimensional periodic-optical-intensity pattern in the photosensitive material.

15. The photo-mask of claim 14, wherein the plurality of diffractive elements are distributed substantially throughout the body element.

16. The photo-mask of claim 14, wherein the at least one three-dimensional functional-element-producing feature comprises a plurality of three-dimensional functional-element-producing features disposed within the body element and distributed substantially throughout the body element.

17. The photo-mask of claim 14, wherein the plurality of diffractive elements are disposed within a first portion of the body element and the at least one three-dimensional functional-element-producing feature is disposed within a second portion of the body element that is separate from the first portion.

18. The photo-mask of claim 14, wherein the plurality of diffractive elements are disposed within an upper portion of the body element and the at least one three-dimensional functional-element-producing feature is disposed within a lower portion of the body element.

19. The photo-mask of claim 17, wherein the plurality of diffractive elements disposed within the first portion of the body element comprise a plurality of layers of diffractive elements positioned in an upper portion of the body element.

20. The photo-mask of claim 17, wherein the at least one three-dimensional functional-element-producing feature disposed within the second portion of the body element comprises a plurality of layers of functional-element-producing features disposed within a lower portion of the body element.

21. The photo-mask of claim 14, wherein the plurality of diffractive elements comprise at least one diffractive grating.

22. The photo-mask of claim 14, wherein the at least one three-dimensional functional-element-producing feature comprises at least one of a channel and a waveguide.

23. The photo-mask of claim 14, wherein the at least one diffractive element is configured to produce, upon illumination of the photo-mask, an umbrella configuration of beams.

24. A method for fabricating a three-dimensional structure by optical lithography, comprising:
producing, by at least one diffractive element of a photo-mask, multiple beams to form a three-dimensional periodic-optical-intensity pattern in a photosensitive material; and
producing, by at least one functional-element-producing feature of the photo-mask, a corresponding functional element pattern as an increased optical intensity pattern or decreased optical intensity pattern within the three-dimensional periodic-optical-intensity pattern in the photosensitive material.

25. The method of claim 24, wherein producing the functional element periodic-optical-intensity pattern by the at least one functional-element-producing feature comprises diffracting light by a hologram feature of the functional-element-producing feature.

26. The method of claim 24, wherein producing the functional element periodic-optical-intensity pattern by the at least one functional-element-producing feature comprises attenuating light by an absorption volume of the functional-element-producing feature.

27. The method of claim 24, wherein producing the functional element periodic-optical-intensity pattern by the at least one functional-element-producing feature comprises producing the functional element optical intensity pattern by a hologram feature and absorption volume of the three-dimensional functional-element-producing feature.

28. The method of claim 24, wherein the at least one diffractive element occupies only a portion of the volume of the body element.

29. The method of claim 24, wherein producing the multiple beams to form the three-dimensional periodic-optical-intensity pattern in the photosensitive material comprises producing, by the at least one diffractive element, the multiple beams to generate an interference pattern in the photosensitive material.

30. The method of claim 24, wherein producing the functional element periodic-optical-intensity pattern by the at least one functional-element-producing feature comprises producing, by the at least one functional-element-producing feature, a three-dimensional non-periodic optical intensity pattern in the photosensitive material.

31. The method of claim 24, further comprising introducing, by at least one beam conditioner, at least one of polarization adjustment, amplitude adjustment, and phase shifting in the multiple beams produced by the at least one diffractive element.

32. The method of claim 31, wherein the at least one beam conditioner comprises a transmissive or reflective spatial light modulator positioned in the Fourier plane.
